(19) United States
(12) Patent Application Publication
(10) Pub. No.: US 2010/0155232 A1
(43) Pub. Date: Jun. 24, 2010

(54) METHOD FOR MANUFACTURING A MAGNETIC WRITE HEAD HAVING A WRITE POLE TRAILING EDGE TAPER

(76) Inventors: Aron Pentek, San Jose, CA (US); Sue Siyang Zhang, Saratoga, CA (US); Yi Zheng, San Ramon, CA (US)

Correspondence Address: ZILKA-KOTAB, PC- HIT, P.O. BOX 721120, SAN JOSE, CA, 95172-1120, US

(21) Appl. No.: 12/343,014

(22) Filed: Dec. 23, 2008

(51) Int. Cl. C23C 14/00

(52) U.S. Cl. 204/192.34

(57) ABSTRACT

A method for manufacturing a magnetic write head for perpendicular magnetic data recording, having a write pole with a tapered trailing edge for improved write field at small bit lengths. The trailing edge taper is formed by a deposition process that can be performed after the write pole flare point has already been formed, and especially after a wrap around shield side gap has been formed. This advantageously allows the distance between the write pole flare point and the trailing edge taper to be closely controlled.

### FIELD OF THE INVENTION

The present invention relates to perpendicular magnetic recording and more particularly to a magnetic write head having a write pole with a tapered trailing edge for increased write field strength at small bit length dimensions.

### BACKGROUND OF THE INVENTION

The heart of a computer's long term memory is an assembly that is referred to as a magnetic disk drive. The magnetic disk drive includes a rotating magnetic disk, write and read heads that are suspended by a suspension arm adjacent to a surface of the rotating magnetic disk and an actuator that swings the suspension arm to place the read and write heads over selected circular tracks on the rotating disk. The read and write heads are directly located on a slider that has an air bearing surface (ABS). The suspension arm biases the slider toward the surface of the disk, and when the disk rotates, air adjacent to the disk moves along with the surface of the disk. The slider flies over the surface of the disk on a cushion of this moving air. When the slider rides on the air bearing, the write and read heads are employed for writing magnetic transitions to and reading magnetic transitions from the rotating disk. The read and write heads are connected to processing circuitry that operates according to a computer program to implement the writing and reading functions.

The write head has traditionally included a coil layer embedded in first, second and third insulation layers (insulation stack), the insulation stack being sandwiched between first and second pole piece layers. A gap is formed between the first and second pole piece layers by a gap layer at an air bearing surface (ABS) of the write head and the pole piece layers are connected at a back gap. Current conducted to the coil layer induces a magnetic flux in the pole pieces which causes a magnetic field to fringe out at a write gap at the ABS for the purpose of writing the aforementioned magnetic transitions in tracks on the moving media, such as in circular tracks on the aforementioned rotating disk.

In recent read head designs, a GMR or TMR sensor has been employed for sensing magnetic fields from the rotating magnetic disk. The sensor includes a nonmagnetic conductive layer, or barrier layer, sandwiched between first and second ferromagnetic layers, referred to as a pinned layer and a free layer. First and second leads are connected to the sensor for conducting a sense current therethrough. The magnetization of the pinned layer is pinned perpendicular to the air bearing surface (ABS) and the magnetic moment of the free layer is located parallel to the ABS, but free to rotate in response to external magnetic fields. The magnetization of the pinned layer is typically pinned by exchange coupling with an antiferromagnetic layer.

The thickness of the spacer layer is chosen to be less than the mean free path of conduction electrons through the sensor. With this arrangement, a portion of the conduction electrons is scattered by the interfaces of the spacer layer with each of the pinned and free layers. When the magnetizations of the pinned and free layers are parallel with respect to one another, scattering is minimal and when the magnetizations of the pinned and free layer are antiparallel, scattering is maximized. Changes in scattering alter the resistance of the spin valve sensor in proportion to cos Θ, where Θ is the angle between the magnetizations of the pinned and free layers. In a read mode the resistance of the spin valve sensor changes proportionally to the magnitudes of the magnetic fields from the rotating disk. When a sense current is conducted through the spin valve sensor, resistance changes cause potential changes that are detected and processed as playback signals.

In order to meet the ever increasing demand for improved data rate and data capacity, researchers have recently been focusing their efforts on the development of perpendicular recording systems. A traditional longitudinal recording system, such as one that incorporates the write head described above, stores data as magnetic bits oriented longitudinally along a track in the plane of the surface of the magnetic disk. This longitudinal data bit is recorded by a fringing field that forms between the pair of magnetic poles separated by a write gap.

A perpendicular recording system, by contrast, records data as magnetizations oriented perpendicular to the plane of the magnetic disk. The magnetic disk has a magnetically soft underlayer covered by a thin magnetically hard top layer. The perpendicular write head has a write pole with a very small cross section and a return pole having a much larger cross section. A strong, highly concentrated magnetic field emits from the write pole in a direction perpendicular to the magnetic disk surface, magnetizing the magnetically hard top layer. The resulting magnetic flux then travels through the soft underlayer, returning to the return pole where it is sufficiently spread out and weak that it will not erase the signal recorded by the write pole when it passes back through the magnetically hard top layer on its way back to the return pole.

### SUMMARY OF THE INVENTION

The present invention provides a method for manufacturing a magnetic write head for perpendicular magnetic data recording that has a write pole with a tapered trailing edge for improved write field at small bit lengths. The trailing edge taper is formed by a deposition process that can be performed after the write pole flare point has already been formed. This advantageously allows the distance between the write pole flare point and the trailing edge taper to be closely controlled.

Accordingly, the write pole can be first formed by depositing a magnetic write pole material and then forming a mask structure over the write pole material. An ion milling process can be performed to define the shape of the write pole including flare point. Other processes can be performed to form non-magnetic side gap layers at either side of the write pole. Then, a mask can be formed over the write pole, the mask having a back edge that is located so as to define a location of the trailing edge taper. A magnetic material can then be deposited over the write pole and mask such that the back edge of the mask defines location of the front of the magnetic layer. This layer of magnetic material thickens the write pole at a desired location removed from the air bearing surface.

The mask can be a bi-layer mask having an overhanging portion and an undercut portion. This can allow the deposited magnetic material to form a tapered front edge at the location of the overhang. This tapered front edge advantageously forms a desired taper on the trailing edge of the write pole.

These and other features and advantages of the invention will be apparent upon reading of the following detailed description of preferred embodiments taken in conjunction with the Figures in which like reference numerals indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a disk drive system in which the invention might be embodied;

FIG. 2 is an ABS view of a slider, taken from line 2-2 of FIG. 1, illustrating the location of a magnetic head thereon;

FIG. 3 is a cross sectional view of a magnetic head, taken from line 3-3 of FIG. 2 and rotated 90 degrees counterclockwise, of a magnetic head according to an embodiment of the present invention; and

FIGS. 4-15 show a portion of a write head in various intermediate smuts of manufacture illustrating a method for manufacturing a write head according to an embodiment of the invention.

### DETAILED DESCRIPTION OF THE EMBODIMENTS

The following description is of the best embodiments presently contemplated for carrying out this invention. This description is made for the purpose of illustrating the general principles of this invention and is not meant to limit the inventive concepts claimed herein.

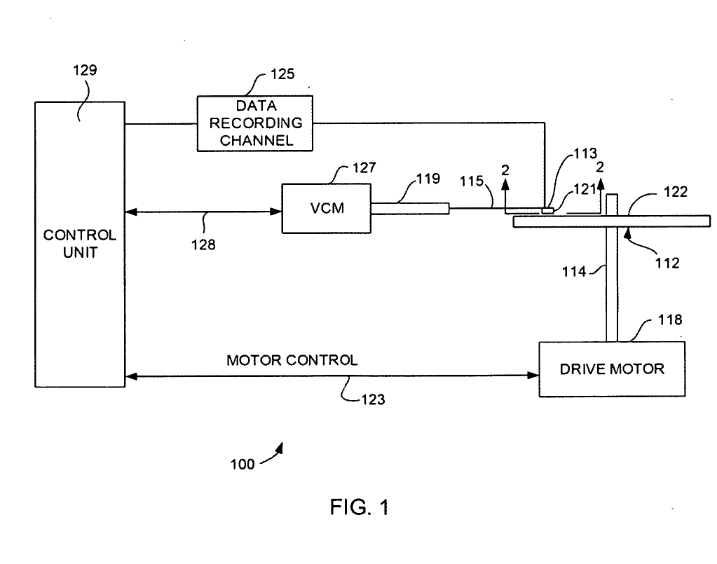

Referring now to FIG. 1, there is shown a disk drive 100 embodying this invention. As shown in FIG. 1, at least one rotatable magnetic disk 112 is supported on a spindle 114 and rotated by a disk drive motor 118. The magnetic recording on each disk is in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, slider 113 moves radially in and out over the disk surface 122 so that the magnetic head assembly 121 may access different tracks of the magnetic disk where desired data are written. Each slider 113 is attached to an actuator arm 119 by way of a suspension 115. The suspension 115 provides a slight spring force which biases slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of the magnetic disk 112 generates an air bearing between the slider 113 and the disk surface 122 which exerts an upward force or lift on the slider. The air bearing thus counter-balances the slight spring force of suspension 115 and supports slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads 121 by way of recording channel 125.

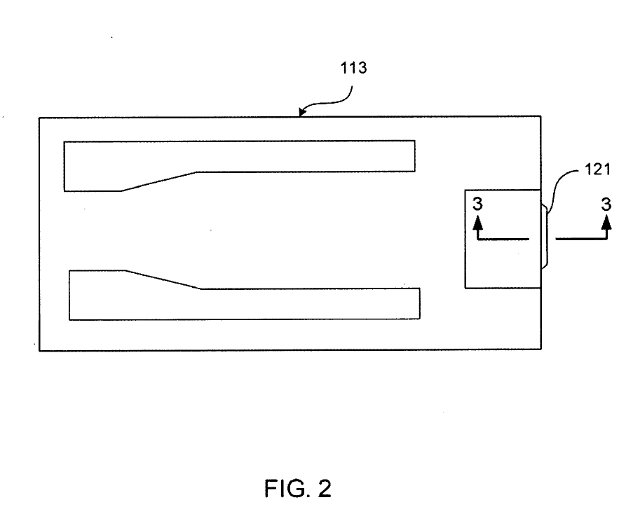

With reference to FIG. 2, the orientation of the magnetic head 121 in a slider 113 can be seen in more detail. FIG. 2 is an ABS view of the slider 113, and as can be seen the magnetic head including an inductive write head and a read sensor, is located at a trailing edge of the slider. The above description of a typical magnetic disk storage system, and the accompanying illustration of FIG. 1 are for representation purposes only. It should be apparent that disk storage systems may contain a large number of disks and actuators, and each actuator may support a number of sliders.

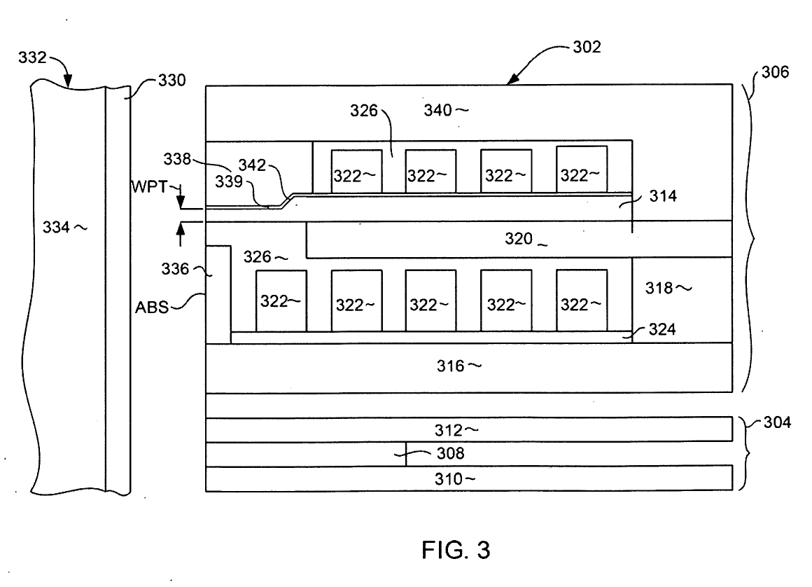

With reference now to FIG. 3, the invention can be embodied in a magnetic head 302. The magnetic head 302 includes a read head 304 and a write head 306. The read head 304 includes a magnetoresistive sensor 308, which can be a GMR, TMR, or some other type of sensor. The magnetoresistive sensor 308 is located between first and second magnetic shields 310, 312.

The write head 306 includes a magnetic write pole 314 and a magnetic return pole 316. The write pole 314 can be formed upon a magnetic shaping layer 320, and a magnetic back gap layer 318 magnetically connects the write pole 314 and shaping layer 320 with the return pole 316 in a region removed from the air bearing surface (ABS). A write coil 322 (shown in cross section in FIG. 3) passes between the write pole and shaping layer 314, 320 and the return pole 316, and may also pass above the write pole 314 and shaping layer 320. The write coil 322 can be a helical coil or can be one or more pancake coils. The write coil 322 can be formed upon an insulation layer 324 and can be embedded in a coil insulation layer 326 such as alumina and or hard baked photoresist.

In operation, when an electrical current flows through the write coil 322, a resulting magnetic field causes a magnetic flux to flow through the return pole 316, back gap 318, shaping layer 320 and write pole 314. This causes a magnetic write field to be emitted from the tip of the write pole 314 toward a magnetic medium 332. The write pole 314 has a cross section at the ABS that is much smaller than the cross section of the return pole 316 at the ABS. Therefore, the magnetic field emitting from the write pole 314 is sufficiently dense and strong that it can write a data bit to a magnetically hard top layer 330 of the magnetic medium 332. The magnetic flux then flows through a magnetically softer under-layer 334, and returns back to the return pole 316, where it is sufficiently spread out and weak that it does not erase the data bit recorded by the write pole 314. A magnetic pedestal 336 may be provided at the air bearing surface ABS and attached to the return pole 316 to prevent stray magnetic fields from the bottom leads of the write coil 322 from affecting the magnetic signal recorded to the medium 332.

In order to increase write field gradient, and therefore increase the speed with which the write head 306 can write data, a trailing, wrap-around magnetic shield 338 can be provided. The trailing, wrap-around magnetic shield 338 is separated from the write pole by a non-magnetic layer 339. The shield 338 also has side shielding portions that are separated from sides of the write pole by non-magnetic side gap layers. The side portions of the shield 338 and side gap portions are not shown in FIG. 3, but will be described in greater detail herein below. The trailing shield 338 attracts the magnetic field from the write pole 314, which slightly cants the angle of the magnetic field emitting from the write pole 314. This canting of the write field increases the speed with which write field polarity can be switched by increasing the field gradient. A trailing magnetic return pole 340 can be provided and can be magnetically connected with the trailing shield 338. Therefore, the trailing return pole 340 can magnetically connect the trailing magnetic shield 338 with the back portion of the write pole 302, such as with the back end of the shaping layer 320 and with the back gap layer 318. The magnetic trailing shield is also a second return pole so that in addition to magnetic flux being conducted through the medium 332 to the return pole 316, the magnetic flux also flows through the medium 332 to the trailing return pole 340.

In order to increase data density in a magnetic data recording system, the bit length of the recorded data bits must be decreased. This requires a reduction of the write pole thickness WPT as measured from the trailing edge to the leading edge of the write pole as shown in FIG. 3. However, this reduction in write pole thickness WPT risks magnetically saturating the write pole so that magnetic flux to the tip of the write pole 314 can become choked off, thereby reducing write field strength. In order to mitigate this, the write pole 314 has a tapered leading edge 342 where the thickness of the write pole increases at a location somewhat removed from the air bearing surface ABS. The location of the trailing edge taper 342 is preferably behind the flare point, as will be described in greater detail below.

Prior art methods for forming a trailing edge taper 342 have required that the taper 342 be formed prior to the definition of the write pole flare point (the flare point to be described herein below). This, however, makes the accurate definition of the flare point more difficult and time consuming due to factors such as topography during the flare point definition. This also makes it difficult to accurately locate the taper 342 relative to the flare point.

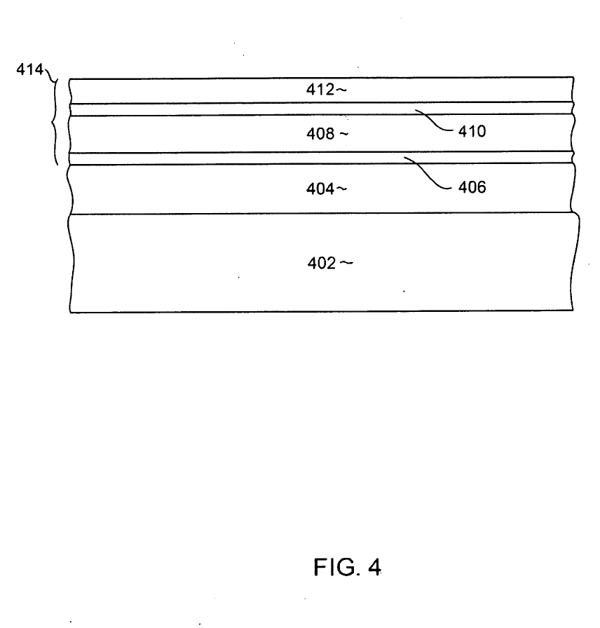

With reference to FIGS. 4-15, the present invention provides a method for manufacturing a write head that allows the trailing edge taper to be formed by a deposition process after the definition of the flare point and subsequent wrap around shield side gap formation. With particular reference to FIG. 4, a substrate 402 is provided. This substrate 402 can include an alumina fill layer such as the layer 326 of FIG. 3 and may also include the magnetic shaping layer 320 shown in FIG. 3. A layer of magnetic write pole material 404 is deposited over the substrate 402. This magnetic write pole is preferably a lamination of layers of high magnetic moment material separated by thin layers of non-magnetic material. A series of one or more mask layers 414 are then deposited over the write pole material 404. The series of mask layers 414 can include a non-magnetic first hard mask 406 formed directly on the write pole 404. The first mask layer 406 usually is a lamination of layers of different non-magnetic materials like Al₂O₃, SiO₂, SiON, Ta, TaO, Ta₂O₅, DLC, C, Ru, Ir, Rh, etc. For process described here, 406 preferably will have a RIEable layer at the most bottom of lamination layer of 406 so that layer 404 can be exposed by remove any remaining portion of layer 406 by reactive ion etch as will be more clear in detailed description below. An image transfer layer 408 can be deposited over the non-magnetic first hard mask layer 406. The image transfer layer 408 can be a soluble polyimide material such as DURAMIDE® or some other suitable material. A second hard mask 410, may be provided over the image transfer layer 408. A patternable material such as photoresist 412 is deposited at the top of the series of mask layers 414.

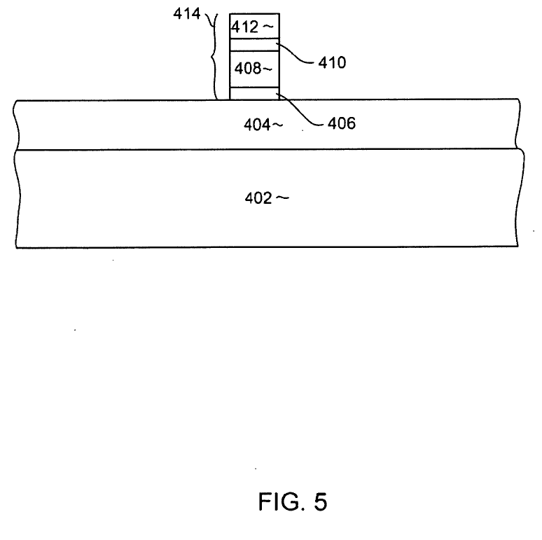

With reference now to FIG. 5, the photoresist layer 412 is photolithographically patterned and developed to define the image of a desired write pole (such as the write pole 314 of FIG. 3). This is shown in cross section in FIG. 5 in a plane parallel with the air bearing surface (ABS). Then, the image of the photoresist layer 412 is transferred onto the underlying mask layers 406, 408, 410. This may include one or more steps of reactive ion milling and/or reactive ion etching (RIE) and/or ion milling.

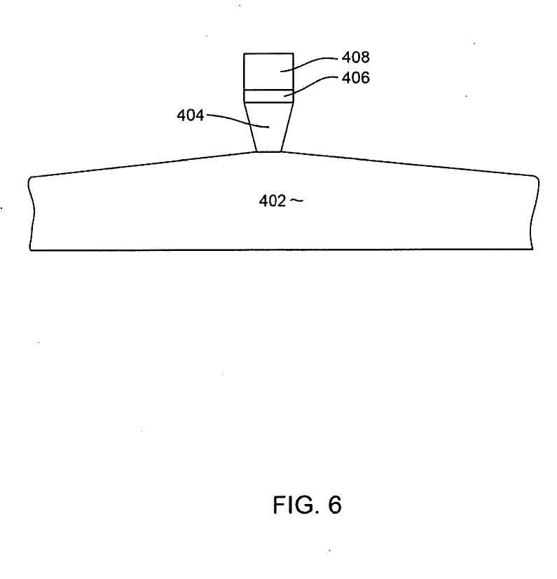

A sweeping ion milling is then performed to remove portions of the magnetic write pole material 404 that are not protected by the overlying mask layers 406, 408, 410, 412. This ion milling process may also be used to transfer the image of the layers 408, 410, 412 onto the first hard mask layer 406. This sweeping ion milling can be performed at one or more angles relative to normal in order to form the remaining write pole material 404 with tapered sides, resulting in the write pole 404 having a trapezoidal shape as shown in FIG. 6. This sweeping ion milling likely removes some of the series of mask layers 414, such as layers 412, 410, and a portion of layer 410, leaving layers 406, 408 as shown in FIG. 6. A wet and/or dry stripping process will be applied to remove soluble polyimide material 408.

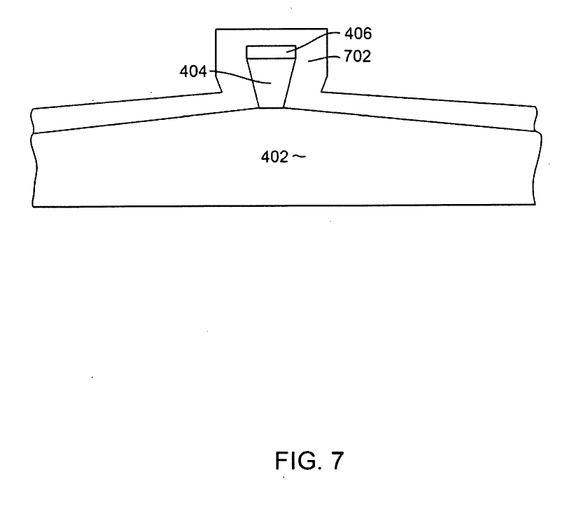

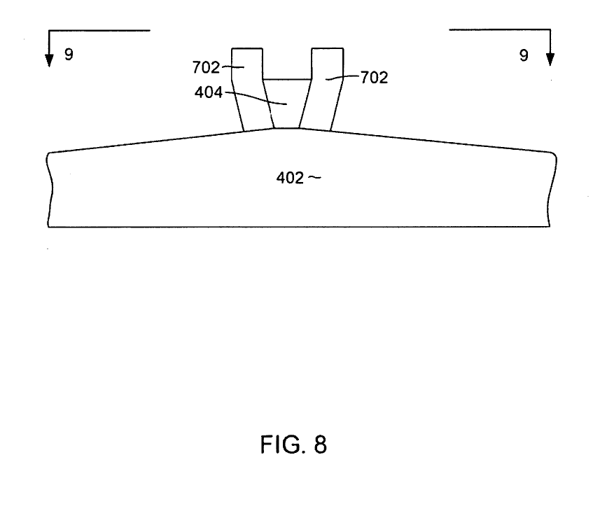

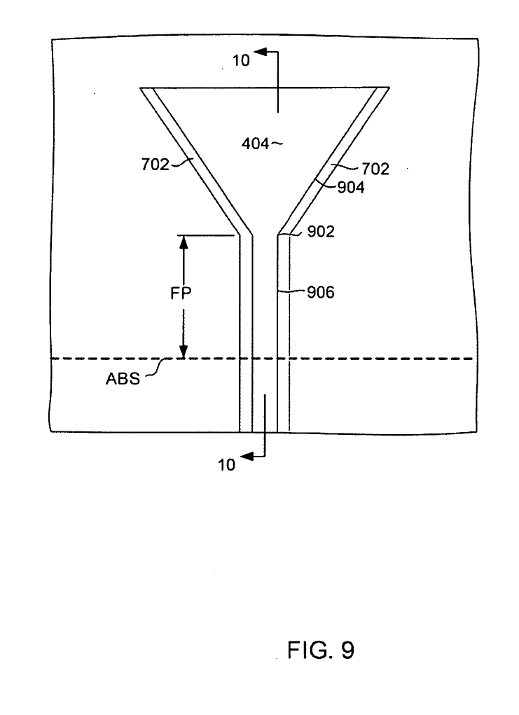

Then, with reference to FIG. 7 a layer of non-magnetic side gap material 702 is deposited. This side gap material 702 is preferably alumina, deposited by a conformal deposition process such as atomic layer deposition or chemical vapor deposition. Then, with reference to FIG. 8, direction material removal process such as ion milling is performed to preferentially remove horizontally disposed portions of the alumina layer 702, which will be end point stopped inside layer 406 and will only leave the bottom portion or RIEable portion of 406 over 404. Then reactive ion etch can be used to remove remaining 406 and expose 404. This results in non-magnetic side walls 702 being formed at either side of the write pole 404. The resulting structure can be seen in FIG. 9, which shows a top down view taken from line 9-9 of FIG. 8. FIG. 9 shows a write pole 404 formed over a substrate 402. The non-magnetic side walls 702 can be seen at either side of the write pole 404. Dashed line denoted as ABS indicates a desired location of an air bearing surface plane, which although not yet formed, will be formed in a subsequent lapping process (not shown). The write pole 404 has a flare point 902, which is a point at which the flared portion 904 of the write pole 404 meets the narrow pole tip portion 906 of the write pole 404. As can be seen, the flare point is located a desired flare point distance (FP) from the ABS.

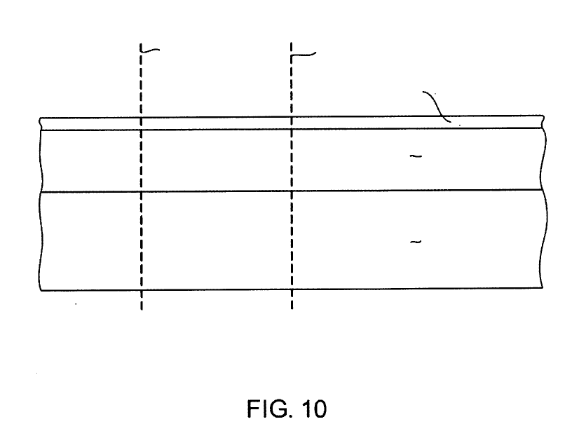

FIG. 10 shows a cross sectional view as taken from line 10-10 of FIG. 9. A thin protective layer 1002 is deposited full film. This thin protective layer 1002 is preferably a non-magnetic material that is resistant to damage by developer solution. The thin layer 1002 is more preferably NiCr, but can also be any non-magnetic materials such as Ru, Ir, Rh, Ta, TaO, Ta₂O₅, etc. As mentioned above, the write pole material 404 is preferably a lamination of layers of high moment magnetic material separated by thin layers of non-magnetic material. This construction avoids the formation of magnetic domains and increases the speed of magnetic switching. Similarly, the layer 1002 can be deposited sufficiently thin that it can function as one of the thin non-magnetic layers of the laminated write pole material 404. Therefore, the protective layer 1002 is preferably less than 5 nm thick and is more preferably about 3 nm thick. In FIG. 10, the dashed line denoted ABS indicates the location of the intended air bearing surface plane, and the dashed line denoted as 1004 indicates the location of the flare point (902 in FIG. 9).

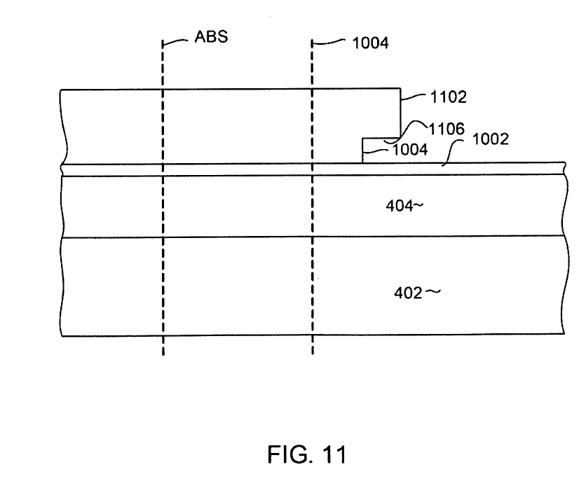

Then, with reference to FIG. 11, a bi-layer photoresist mask 1102 is formed over the protective layer 1102. The bi-layer resist mask 1002 has lower undercut portion having a back edge 1104 and an overhanging portion with a back edge 1106. The edges 1104 and 1106 are located so as to define a location of tapered trailing edge as will be seen below. The protective layer 1002 protects the alumina side walls 702 (FIG. 9) from being damaged by the developer that is used in the formation of the mask 1102.

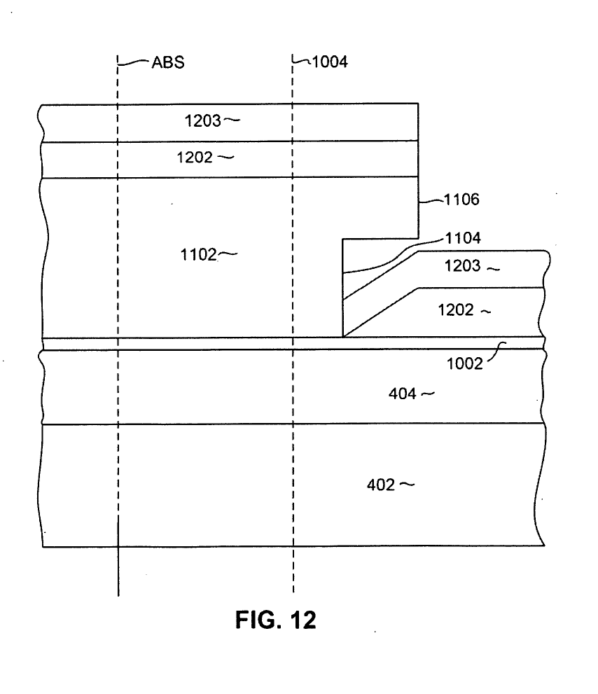

With reference to FIG. 12, a layer of magnetic material 1202 is deposited. The magnetic material 1202 is preferably a high magnetic moment material such as CoFe or CoNiFe and is preferably deposited by a directional sputter deposition method like IBD. The magnetic material 1202 is preferably deposited to a thickness of 20 to 60 nm or about 50 nm. Another layer of nonmagnetic material 1203 such as NiCr, Ru, Ir, Rh, Ta, TaO, etc., can be deposited with same method over magnetic layer 1202 to serve as a spacer between subsequently built shield and the layer 1202 to avoid flux leakage. This nonmagnetic layer can have thickness between 20 nm to 60 nm. As can be seen, the magnetic material 1202, when deposited, extends under the overhanging edge 1106. This causes the magnetic material 1202 to form a desired tapered edge 1204, which terminates beneath the overhanging portion at the undercut edge 1104.

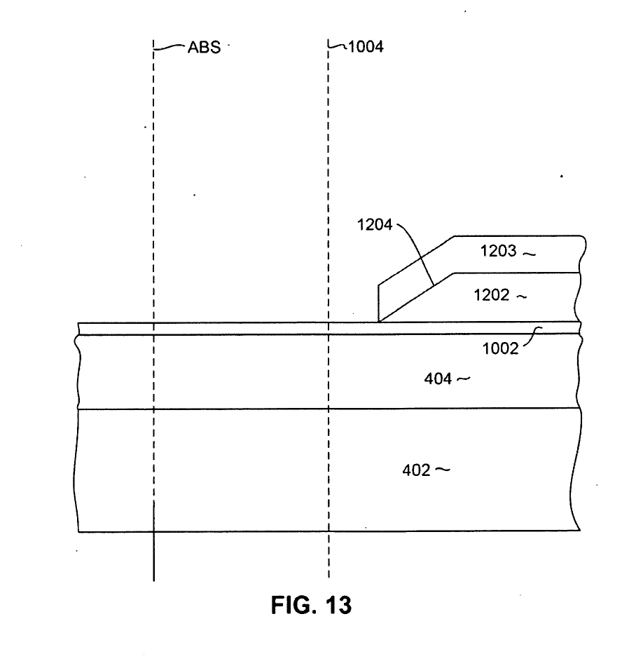

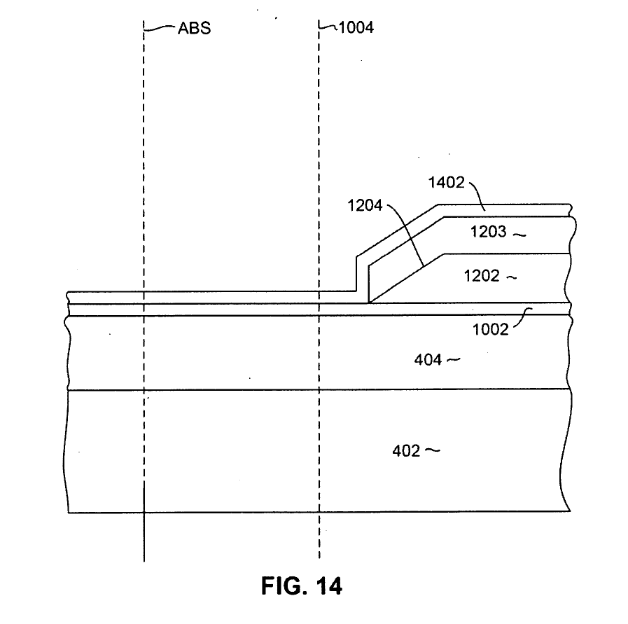

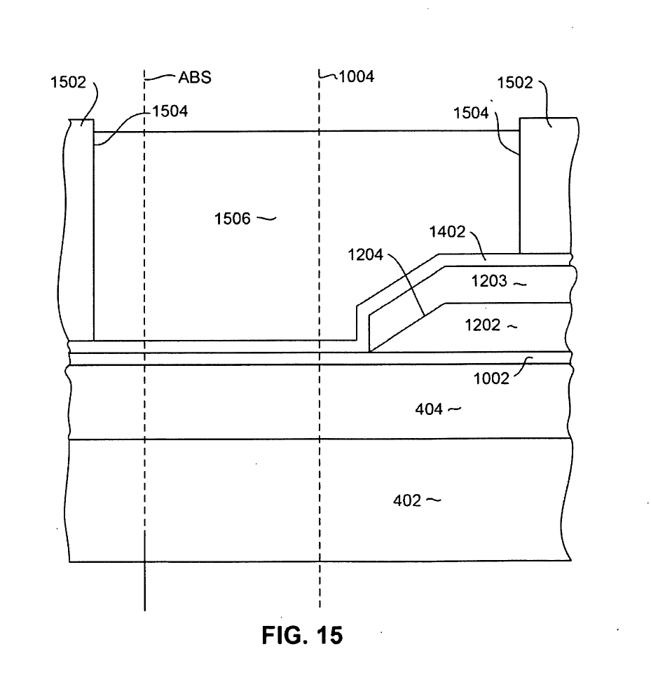

Then, the mask 1102 can be lifted of leaving a structure such as that shown in FIG. 13. Then, with reference to FIG. 14, a non-magnetic, electrically conductive seed layer 1402 is deposited. The seed layer 1402 can be a material such as Rh, or Ru, Ir or some other electrically conductive, non-magnetic material, and is deposited to a thickness that will define a trailing shield gap thickness. Then, with reference to FIG. 15, an electroplating frame mask 1502 is constructed having an opening 1504 that is configured to define the shape of a trailing wrap around shield. A magnetic material 1506 such as NiFe or CoFe is then electroplated into the opening 1504 in the mask. The mask 1502 can then be lifted off, leaving the shield 1506, which corresponds to the shield 338 of FIG. 3. The above described method for manufacturing a write head allows for trailing edge taper definition of the write pole 404. This method is especially useful for writer pole formed by a dry etch process and wrap around shield process. Flare point data can be fed forward in the process so that the distance between the flare point location 1004 and the trailing edge taper 1204 can be closely and accurately controlled.

While various embodiments have been described, it should be understood that they have been presented by way of example only, and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A method for manufacturing a magnetic write head, comprising:
providing a substrate;
depositing a magnetic write pole material over the substrate;
forming a first mask structure over the magnetic write pole material, the first mask structure being configured to define a write pole having a flare point;
performing an ion milling to remove portions of the write pole material that are not protected by the first mask structure, thereby forming a write pole having a flare point;
after performing the ion milling, forming a non-magnetic side wall on a side of the write pole;
after forming the non-magnetic side wall, forming a second mask structure over the write pole, the second mask structure having a back edge located at a trailing edge taper location;
depositing a magnetic material; and
removing the second mask structure.

2. A method as in claim 1 wherein the second mask structure is a bi-layer mask structure having an undercut portion and an overhanging portion.

3. A method as in claim 1 further comprising, after performing the ion milling, forming first and second non-magnetic side walls at first and second sides of the write pole.

4. A method as in claim 1 further comprising after performing the ion milling, depositing a non-magnetic material, and then performing a material removal process to form first and second non-magnetic side walls at first and second sides of the write pole.

5. A method as in claim 1 further comprising, after performing the ion milling, remaining portions of the first mask structure.

6. A method as in claim 1 further comprising, after performing the ion milling, and before forming the second mask structure, depositing a thin protective layer.

7. A method as in claim 6 wherein the protective layer comprises NiCr, or Ru, Ir, Rh, TaO, Ta, etc.

8. A method as in claim 6 wherein the protective layer has a thickness not greater than 5 nm.

9. A method as in claim 6 wherein the protective layer has a thickness of about 3 nm.

10. A method as in claim 6 wherein the protective layer comprises NiCr and has a thickness of about 3 nm.

11. A method as in claim 1 wherein the magnetic write pole material is a lamination of layers of magnetic material separated by thin layers of non-magnetic material.

12. A method as in claim 3 wherein the non-magnetic side walls comprise alumina.

13. A method as in claim 4 wherein the non-magnetic material comprises alumina deposited by atomic layer deposition and wherein the material removal process used to form the first and second side walls comprises ion milling.

14. A method as in claim 1 wherein the magnetic material comprises CoFe.

15. A method as in claim 1 wherein the magnetic material has a thickness of 20-60 nm.

16. A method as in claim 1 wherein the magnetic material has a thickness of about 50 nm.

17. A method as in claim 1 wherein the magnetic material comprises CoFe and is deposited to a thickness of about 50 nm.

18. A method as in claim 1 further comprising, after removing the second mask structure:
depositing a non-magnetic, electrically conductive seed layer;
forming a third mask structure, the third mask structure having an opening configured to define a trailing, wrap-around shield,
electroplating a magnetic material into the opening in the third mask structure; and
removing the third mask structure.

19. A method as in claim 18 wherein the non-magnetic, electrically conductive seed layer comprises Rh.

20. A method as in claim 18 wherein the non-magnetic, electrically conductive seed layer is deposited to a thickness that is chosen to define a non-magnetic trailing gap.

21. A method as in claim 1 further comprising, after depositing the magnetic material and before removing the second mask structure, depositing a non-magnetic spacer material.
